(19) United States
(12) Patent Application Publication
(10) Pub. No.: US 2008/0242076 A1
(43) Pub. Date: Oct. 2, 2008

(54) METHOD OF MAKING SEMICONDUCTOR DIE STACK HAVING HEIGHTENED CONTACT FOR WIRE BOND

(76) Inventors: Hem Takiar, Fremont, CA (US); Shrikar Bhagath, San Jose, CA (US)

Correspondence Address: VIERRA MAGEN/SANDISK CORPORATION, 575 MARKET STREET, SUITE 2500, SAN FRANCISCO, CA, 94105, US

(21) Appl. No.: 11/693,654

(22) Filed: Mar. 29, 2007

(51) Int. Cl. H01L 21/44

(52) U.S. Cl. 438/617

(57) ABSTRACT

A method of making a semiconductor device is disclosed including die bond pads which are heightened to allow wire bonding of offset stacked die even in tight offset configurations. After a first die is affixed to a substrate, one or more layers of an electrical conductor may be provided on some or all of the die bond pads of the first substrate to raise the height of the bond pads. The conductive layers may for example be conductive balls deposited on the die bond pads of the first substrate using a known wire bond capillary. Thereafter, a second die may be added, and wire bonding of the first die may be accomplished using a known wire bond capillary mounting a wire bond ball on a raised surface of a first semiconductor die bond pad.

### CROSS-REFERENCE TO RELATED APPLICATIONS

The following application is related to U.S. patent application Ser. No. ______ [Attorney Docket No. SAND-01153US1], entitled “Semiconductor Die Stack Having Heightened Contact For Wire Bond,” by Hem Takiar et al., filed the same day as the present application, which application is incorporated herein by reference in its entirety.

### BACKGROUND OF THE INVENTION

1. Field of the Invention

Embodiments of the present invention relate to a method of forming a semiconductor device having tightly offset semiconductor chips, and a semiconductor device formed thereby.

2. Description of the Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While a wide variety of packaging configurations are known, flash memory storage cards may in general be fabricated as system-in-a-package (SiP) or multichip modules (MCM), where a plurality of die are mounted on a substrate. The substrate may in general include a rigid, dielectric base having a conductive layer etched on one or both sides. Electrical connections are formed between the die and the conductive layer(s), and the conductive layer(s) provide an electric lead structure for connection of the die to a host device. Once electrical connections between the die and substrate are made, the assembly is then typically encased in a molding compound to provide a protective package.

A cross-section of a conventional semiconductor package 18 (without molding compound) is shown in FIG. 1. Typical packages include a plurality of semiconductor die (20, 22) affixed to a substrate 26. The die may be affixed to the substrate via die attach adhesive layer 24. Generally, the substrate 26 is formed of a rigid core 28, of for example polyimide laminate. Thin film copper layer(s) 30 may be formed on the core in a desired electrical lead pattern using known photolithography and etching processes. Exposed surfaces of the conductance pattern may be plated for example with one or more layers of gold in a plating process to form contact pads for electrical connection of the semiconductor die to the substrate and electrical connection of the substrate to a host device. The substrate may be coated with a solder mask 36, leaving the contact pads exposed, to insulate and protect the electrical lead pattern formed on the substrate. Bond pads on the semiconductor die may be electrically connected to the plated contact pads on the substrate by wire bonds 34.

It is known to layer semiconductor die on top of each other either with an offset or in a stacked configuration. An offset configuration, shown partially in prior art FIG. 2, includes a first die (20) offset stacked on top of another die (22) so that the bond pads 40 of the lower die are left exposed. After the die are mounted with the desired offset, the die may be wire bonded to contact pads 44 on the substrate with wire bonds 34. One such known wire bonding process is a ball bonding process, which uses a wire bonding device referred to as a wire bonding capillary. A length of wire (typically gold or copper) is fed through a central cavity of the wire bonding capillary. The wire protrudes through a tip of the capillary, where a high-voltage electric charge is applied to the wire from a transducer associated with the capillary tip. The electric charge melts the wire at the tip and the wire forms into a ball (46 in FIG. 2) owing to the surface tension of the molten metal.

As the ball solidifies, the capillary is lowered to the surface of the die bond pad 40 receiving the first end of the wire bond. The surface may be heated to facilitate a better bond. The wire bond ball 47 is deposited on the die bond pad 40 under a load, while the transducer applies ultrasonic energy. The combined heat, pressure, and ultrasonic energy create a bond between the wire bond ball 46 and the die bond pad 40.

The wire is then payed out through the capillary and the wire bond device moves over to the substrate (or other semiconductor) receiving the second end of the wire bond. The second bond, referred to as a wedge or tail bond, is then formed again using heat, pressure and ultrasonic energy, but instead of forming a ball, the wire is crushed under pressure to make the second bond, for example at substrate bond pad 44. The wire bonding device then pays out a small length of wire and tears the wire from the surface of the second bond. The small tail of wire hanging from the end of the capillary is then used to form the wire bond ball for the next subsequent wire bond. The above-described cycle can be repeated about 20 to 30 times per second.

An offset configuration provides an advantage of convenient access to the bond pads on each of the semiconductor die for wire bonding. However, the offset requires a greater footprint on the substrate, where space is at a premium. It is thus desirable to minimize the offset. However, as shown in prior art FIG. 3, offsets smaller than a given amount between die bond pads on a first semiconductor die and the edge of a second semiconductor die stacked thereon can present problems. In particular, even wire bond capillaries specially designed for tight offsets have a neck length, Lₜᵢₚ, beyond which the diameter of the capillary increases by angle θ. With such a capillary, for an upper die having a thickness, T_{die}, as shown, the capillary will crash into the upper die when attempting to place the wire bond ball on the die pad of the lower die.

At present, in order to allow for clearance between an upper die and the capillary, offsets of 250 microns (μm) or more are typically required between die bond pads on a first semiconductor die and the edge of a second semiconductor die stacked thereon. However, at times it is not feasible to maintain a 250 μm clearance due to product size constraints. In such instances, methods other than ball bonding are required. There is therefore a need to allow tighter offset stacked die which may be bonded using a ball bonding process.

### SUMMARY OF THE INVENTION

The present invention, roughly described, relates to a semiconductor device including die bond pads which are heightened to allow wire bonding of offset stacked die even in tight offset configurations. In accordance with embodiments of the invention, after a first die is affixed to a substrate, one or more layers of an electrical conductor may be provided on some or all of the die bond pads of the first die to raise the height of the bond pads. The conductive layers may for example be conductive balls deposited on the die bond pads of the first die using a known wire bond capillary. The size, shape and number of the conductive balls affixed to a given die bond pad may vary in alternative embodiments of the present invention.

After the conductive balls are formed on the die bond pads of the first die, a second die may be affixed to the first die. The first semiconductor die may next be wire bonded to the substrate. A wire bonding capillary having a wire bond ball at its tip may be lowered into contact with a conductive ball, and the wire bond ball may be affixed to the conductive ball using conventional wire bonding techniques. The height of the conductive ball above the surface of the first semiconductor die is provided so that the wire bonding capillary may lower the wire bond ball into contact with the conductive ball without any portion of wire bonding capillary contacting the second semiconductor die.

In a further embodiment of the present invention, instead of forming the conductive balls with a wire bonding capillary, the conductive balls may be formed at the wafer level during fabrication of the semiconductor die itself. In such an embodiment, the conductive balls may be formed by stud bumping, gold bumping, or any known process for forming raised surfaces on a semiconductor die. Such processes are often employed in forming a flip-chip semiconductor die. These processes include but are not limited to plating, evaporation, screen printing, or various deposition processes.

### DESCRIPTION OF THE DRAWINGS

FIG. 1 is a cross sectional side view of a portion of a conventional semiconductor package.

FIG. 2 is an enlarged partial perspective view of an offset semiconductor die with the bottom die wire bonded with a conventional wire bond.

FIG. 3 is a side view of a pair of semiconductor die with a tight offset, illustrating the problem of wire bonding in the prior art using a known wire bonding capillary device with tight offset semiconductor die.

FIG. 4 is a flow chart of the process of forming a semiconductor package according to an embodiment of the present invention.

FIG. 5 is a partial perspective view showing a semiconductor die mounted to a substrate according to embodiments of the present invention.

FIG. 6 is a partial perspective view showing conductive balls mounted to the die bond pads of the semiconductor die according to embodiments of the present invention.

FIG. 7 is a partial perspective view showing a second semiconductor die mounted to the first semiconductor die according to embodiments of the present invention.

FIGS. 8 and 9 are side views showing a wire bond being formed on a conductive ball mounted to a die bond pad of the bottom semiconductor die according to embodiments of the present invention.

FIG. 10 is a partial perspective view showing a bottom die wire bonded to the substrate according to embodiments of the present invention.

FIGS. 11 and 12A are partial perspective views illustrating an alternative embodiment of the present invention.

FIG. 12B is a partial perspective view as in FIG. 11 showing a bottom die reverse wire bonded to the substrate according to an alternative embodiment of the present invention.

FIGS. 13 and 14 are partial perspective views of a further alternative embodiment of the present invention.

FIGS. 15 and 16 are top views of a semiconductor wafer and semiconductor die formed thereon including raised surfaces according to an alternative embodiment of the present invention.

FIG. 17 is a cross sectional side view of a semiconductor package formed according to the present invention.

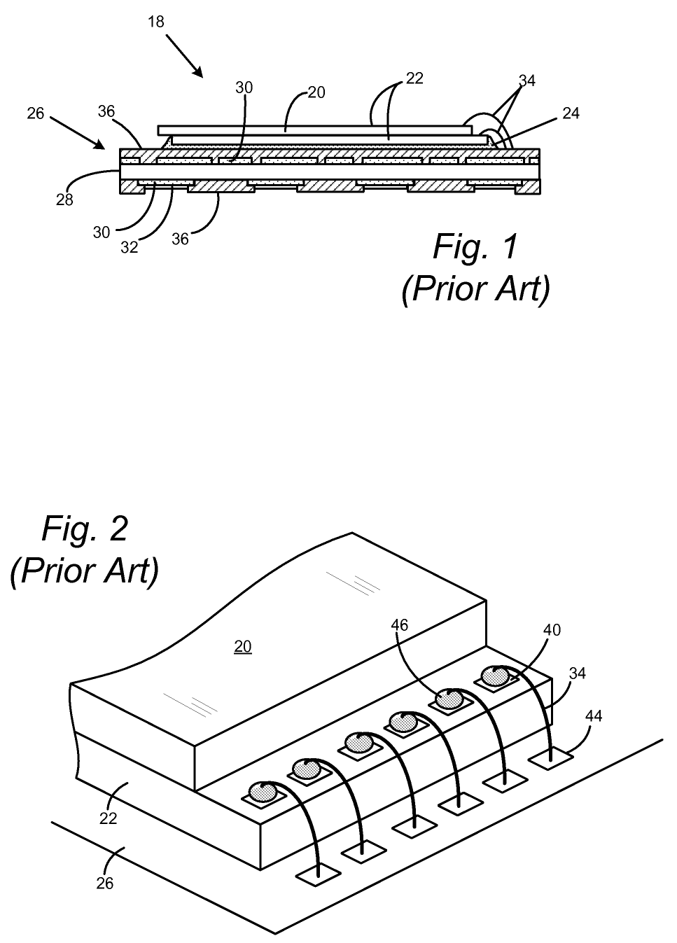

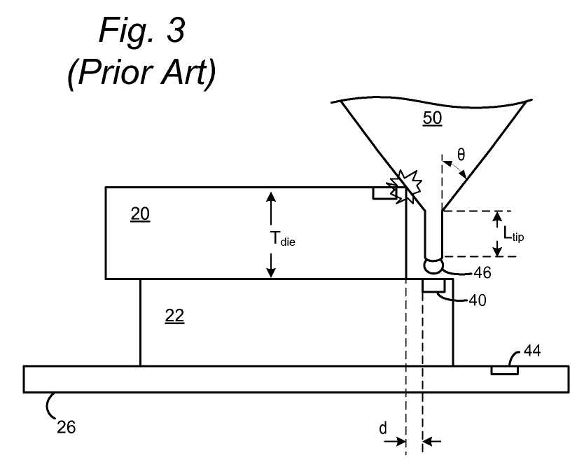

### DETAILED DESCRIPTION

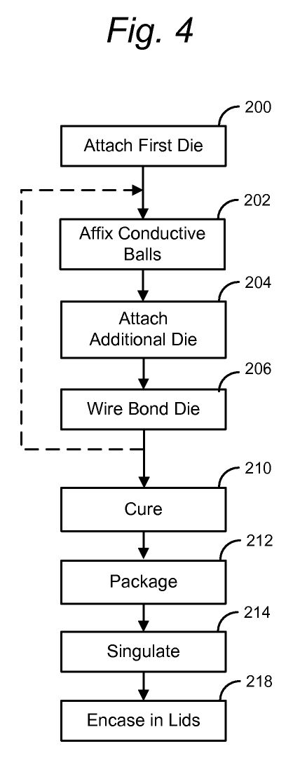

Embodiments will now be described with reference to FIGS. 4 through 17, which relate to a semiconductor device having tightly offset semiconductor die. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

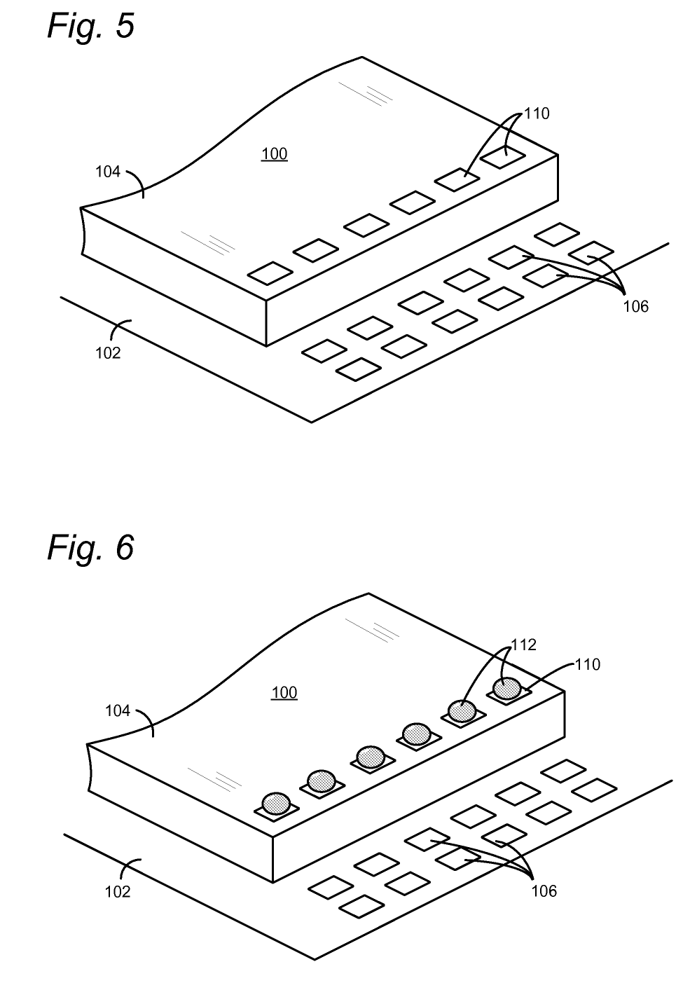

The present invention will now be described with reference to the flowchart of FIG. 4 and the views shown in FIGS. 5-17. Embodiments of the present invention relate to a semiconductor package, including a first semiconductor die 100 mounted in step 200 to a substrate 102 as shown in FIG. 5. The die 100 may be mounted to substrate 102 in a known adhesive or eutectic die bond process using a die attach adhesive layer available for example from Nitto Denko Corp. of Japan, Abelstik Co., California or Henkel Corporation, California. Other die bond processes and manufacturers are contemplated.

Although not critical to the present invention, substrate 102 may be a variety of chip carrier mediums, including a PCB, a leadframe or a tape automated bonded (TAB) tape. Where substrate 102 is a PCB, the substrate may be formed of a core having top and/or bottom conductive layers formed thereon. The core may be various dielectric materials such as for example, polyimide laminates, epoxy resins including FR4 and FR5, bismaleimide triazine (BT), and the like.

The conductive layers may be formed of copper or copper alloys, plated copper or plated copper alloys, Alloy 42 (42FE/58NI), copper plated steel or other metals or materials known for use on substrates. The conductive layers may be etched into a conductance pattern as is known for communicating signals between the semiconductor die and an external device. A dummy pattern may also be provided in the conductive layers as is known to reduce mechanical stresses on the substrate otherwise resulting from uneven thermal expansion within the substrate.

Substrate 102 may additionally include exposed metal portions forming contact pads 106 (FIG. 5). The contact pads 106 may be formed in two or more rows (as shown) so as to receive bond wires from two or more stacked die. The contact pads may alternatively be in a single row for two or more semiconductor die. The contact pads may be plated with one or more gold layers, for example in an electroplating process as is known in the art. The semiconductor die 100 may similarly include bond pads 110 along its edge as is known.

In accordance with embodiments of the invention, in step 204, layers of an electrical conductor may be provided on some or all of die bond pads 110 to raise the height of the bond pads above the surface of die 100, as shown for example in FIG. 6. In embodiments, the conductive layers may be discrete amounts of an electrical conductor, for example balls 112 formed of solder, gold, nickel/gold, aluminum, copper or any of a variety of other metallic electrical conductors. In further embodiments, it is contemplated that conductive balls 112 may be an electrically conductive adhesive of sufficient viscosity to maintain its thickness when deposited on die bond pads 110 of die 100.

In embodiments, conductive balls 112 may be deposited using a conventional wire bonding capillary. For example, in one embodiment, conductive balls 112 may be deposited by forming a ball at the tip of the capillary via a transducer associated with the capillary. The capillary may then be lowered to respective die bond pads 110. The surface 104 of semiconductor die 100 may or may not be heated to facilitate bonding of conductive balls 112. After a ball 112 is formed, the ball 112 may then be deposited on a die bond pad 110 under a load, while the transducer applies ultrasonic energy. The combined heat, pressure, and/or ultrasonic energy create a bond between the conductive ball 112 and the die bond pad 110. The wire bonding device may then pay out a small length of wire, and the wire may be severed at the conductive ball to leave the conductive ball on the die bond pad. The small tail of wire hanging from the end of the capillary may then be used to form the conductive ball 112 for the next subsequent die bond pad 110.

As explained hereinafter, conductive balls 112 may be formed at the bond pads of semiconductor die 100 by a variety of other methods including for example stud bumping or gold bumping at the wafer level, or by a variety of other methods. Although bond pads 110 and conductive balls 112 are shown along a single edge of semiconductor die 100 in FIG. 6, it is understood that bond pads 110 having conductive balls 112 thereon may be provided around two opposed or adjacent edges, three edges or all four edges of semiconductor die 100. In further embodiments, it is contemplated that conductive balls 112 as described herein may additionally or alternatively be provided on one or more of the substrate bond pads 106 to raise the height of bond pads 110.

The size and shape of conductive balls 112 may vary in alternative embodiments of the present invention. In embodiments, conductive balls 112 may each be spherical, ovoid having a length greater than its width or ovoid having a width greater than its length. Such shapes may be formed in a known manner when a wire at the tip of the capillary is melted and then applied to a bond pad in a ball bonding process. It is understood that conductive balls 112 may be other shapes in further embodiments of the present invention. Having a shape as described in any of the embodiments above, each conductive ball 112 may extend above the surface 104 of a semiconductor die 100 to a height which is less than, equal to or greater than the thickness of a second die mounted on die 100 as explained hereinafter. In embodiments, the height of a conductive ball 112 may be a few hundred microns to 5-10 mils, depending in part on a thickness of the semiconductor die used, and the configuration of the wire bonding capillary used. It is understood that the height of conductive balls 112 may be less than a few hundred microns and greater than 10 mils in alternative embodiments of the present invention.

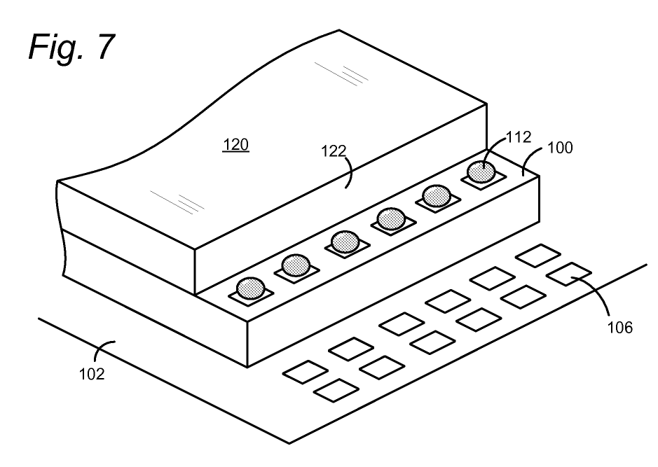

Referring now to FIG. 7, in step 204, after the conductive balls 112 are deposited on bond pads 110, a second semiconductor die 120 having an edge 122 may be mounted on surface 104 of semiconductor die 100. Semiconductor die 120 may be affixed to semiconductor die 100 in a known process using an electrically insulative adhesive, such as for example an epoxy available from Nitto Denko of Japan, Abelstik Co., California or Henkel Corp., California. In embodiments (not shown), an interposer layer as is known in the art may additionally be included between die 100 and die 120. As an interposer layer would effectively raise the height of the second die above the surface of the first die, the height of the conductive ball 112 may be increased accordingly.

The offset of the edge 122 of die 120 from the edge of die 100 may be small or large, with the understanding that at sufficiently large offsets, a conventional wire bond capillary may reach bond pads 110 without the aid of conductive balls 112. In embodiments, the spacing between the edge 122 and the die bond pads 110 may be 250 μm or less, and may be as small as zero microns in embodiments of the present invention.

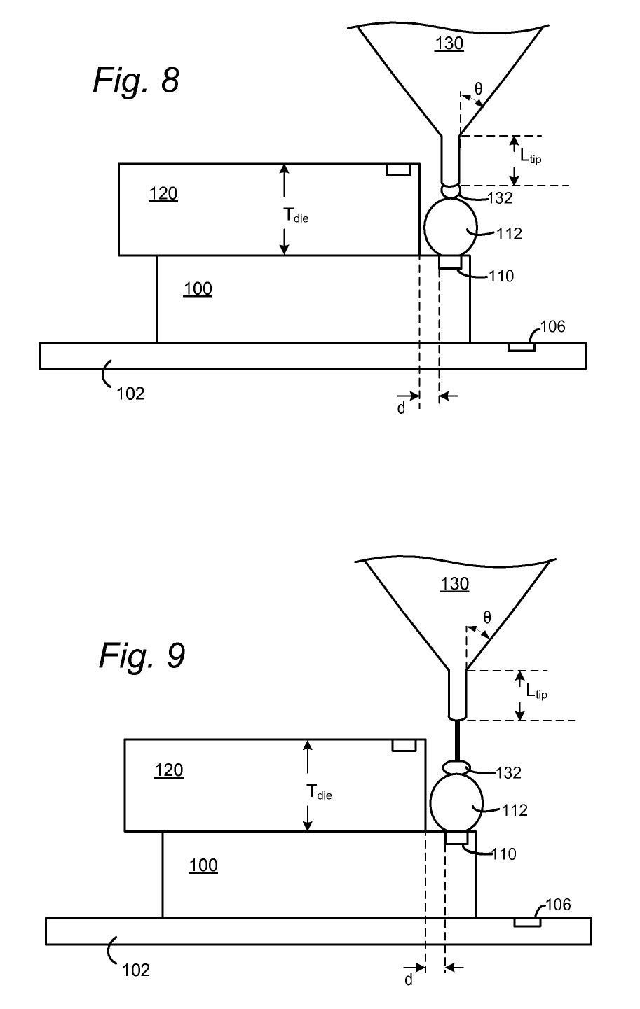

Referring now to FIGS. 8 and 9, in a step 206, semiconductor die 100 may next be wire bonded to the substrate 102. As seen in FIG. 8, a wire bonding capillary 130 having a wire bond ball 132 at its tip may be lowered into contact with conductive ball 112. The configuration of the wire bonding capillary 130 seen in FIGS. 8 and 9 is by way of example only, and it is understood that the present invention may be used with a wide variety of other capillary configurations. After the wire bond ball 132 has been lowered into contact with conductive ball 112, wire bond ball 132 may be affixed to conductive ball 112, such as for example by ultrasonic thermal welding or other known ball bonding techniques. The height of conductive ball 112 above the surface of semiconductor die 100 and bond pad 110 is provided so that the wire bonding capillary 130 may lower the wire bond ball 132 into contact with conductive ball 112 without any portion of wire bonding capillary 130 contacting semiconductor die 120.

In one example, die 120 may have a thickness of 2 mils, and the conductive balls may have a height of 2 mils or greater. In such an example, the die 120 may be spaced any distance, d, from the die bond pads 110 (including zero microns) and there would be no interference between the die bond capillary and the die 120 during a die bond operation on the die 100. In a further embodiment, the wafer may be 500 μm, the conductive balls may have a height of 250 μm and the combined height of the neck, Lₜᵢₚ, and wire bond ball 132 may be 250 μm. Again, in such an embodiment, the die 120 may be spaced any distance, d, from the die bond pads 110 (including zero microns) and there would be no interference between the die bond capillary and the die 120 during a die bond operation on the die 100. Those of skill in the art will appreciate other thicknesses of the conductive balls, based on the thickness of the die 120, the offset, d, and the geometric configuration of the wire bond capillary 130.

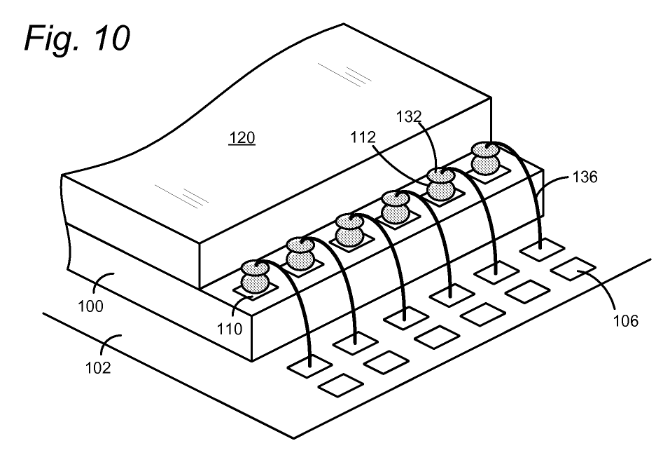

As seen in FIG. 9, after the wire bond ball 132 has bonded to conductive ball 112, wire bonding capillary 130 may move away from the deposited wire bond ball 132, paying out a length of wire 136 which is then bonded to substrate contact pad 106 as is known in the art. This process is repeated until each die bond pad 110 on die 100 is affixed to a contact pad 106 on substrate 102 such as shown for example on FIG. 10. It is understood that one or more of the die bond pads 110 and/or contact pads 106 may be left without a wire bond. The wire bonding capillary 130 used to form the wire bonds as shown in FIGS. 8 and 9 may be the same or different than the wire bonding device used to deposit conductive balls 112 on the surface of the semiconductor 100 as shown in FIG. 6.

In the embodiments shown for example in FIG. 10, semiconductor die 100 and semiconductor die 120 are shown having the same width. However, semiconductor die 120 may have a smaller footprint (length and width) than semiconductor die 100 such that semiconductor die 120 is offset from semiconductor die 100 along two or more adjacent edges. As indicated above, die bond pads 110, conductive balls 112, and wire bonds 136 may accordingly be provided around two or more edges of the lower die 100.

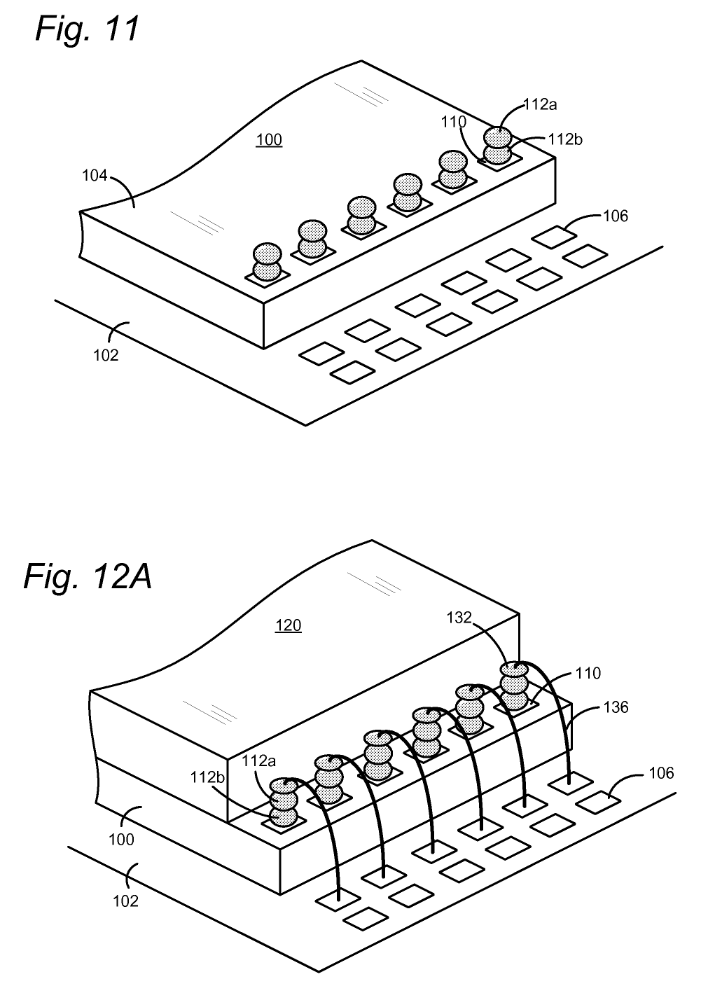

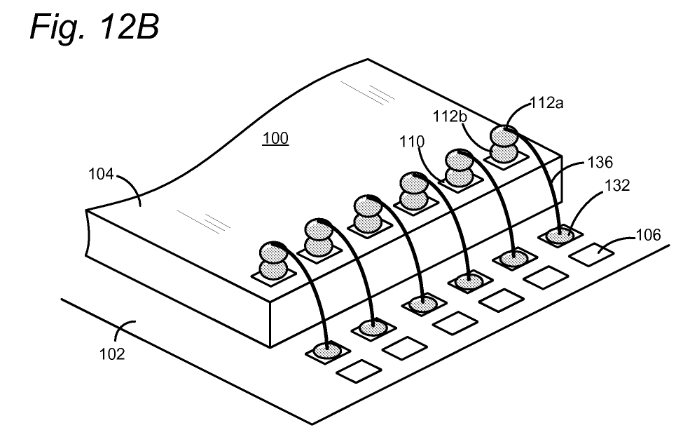

As indicated above, the conductive layers used to raise the height of the wire bond pads of semiconductor die 100 may take a variety of forms. In an embodiment shown in FIGS. 11 and 12A, a pair of conductive balls 112 (112a, 112b) may be bonded to die bond pads 110 one atop the other. Conductive balls 112a, 112b may be bonded to die bond pads 110 by any bonding or deposition methods described herein or otherwise known. The pair of conductive balls 112a, 112b shown in FIGS. 11 and 12A may together have a height which is greater than, equal to or less than the height of a single conductive ball 112 shown in FIGS. 6 through 10. The respective conductive balls 112a and 112b may have the same or different size and the same or different shape as each other. Once the conductive balls 112a, 112b are affixed to semiconductor die 100, wire bonds may be formed between die 100 and substrate 102 as shown in FIG. 12A and as described above.

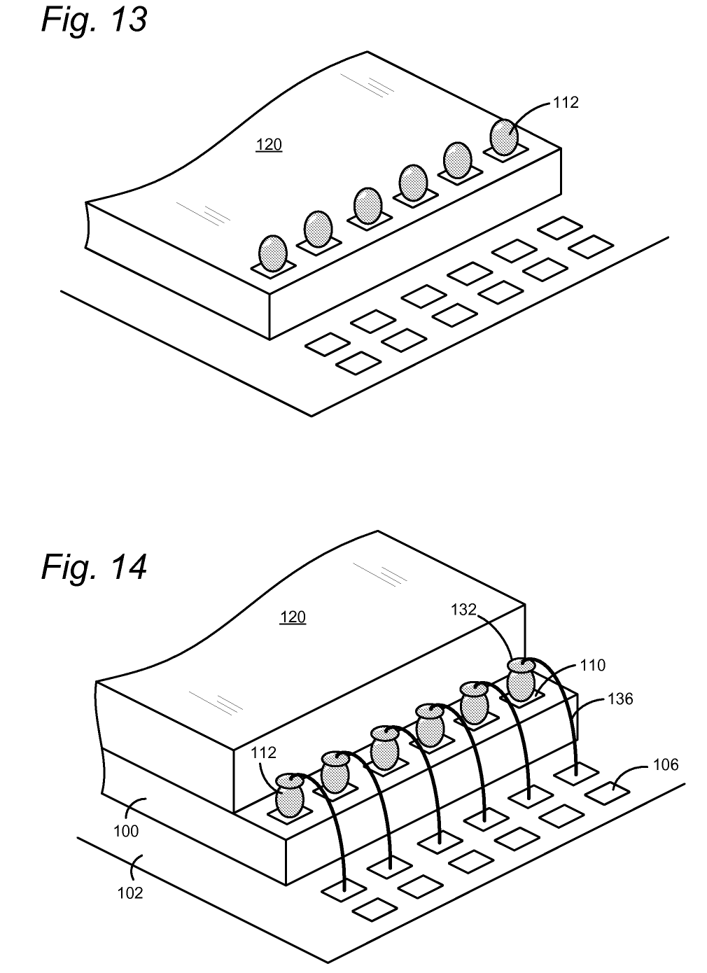

In an alternative embodiment of the present invention shown in FIG. 12B, a wire bond including wire 136 and ball bond 132 may be reverse wire bonded onto conductive balls 112a and 112b shown in FIGS. 11 and 12A. In this embodiment, the capillary forms a ball bond 132 on the substrate pad 106, pays out a length of wire 136, and then reverse bonds the opposite end of wire 136 onto conductive ball 112b, for example in a wedge or tail bond. The embodiment of FIG. 12B may also be used with other embodiments described herein, such as for example the embodiments shown in FIGS. 13 through 14 described below.

As mentioned above, conductive balls 112 may have a shape other than spherical. Such an embodiment is shown in FIGS. 13 and 14. In the embodiment shown in FIGS. 13 and 14, a conductive ball 112 is substantially ovoid having a height greater than its width. The conductive ball 112 shown in FIG. 13 may be formed and deposited on die bond pads 110 according to any of the above-described methods, and thereafter wire bonded to substrate 102 as shown in FIG. 14.

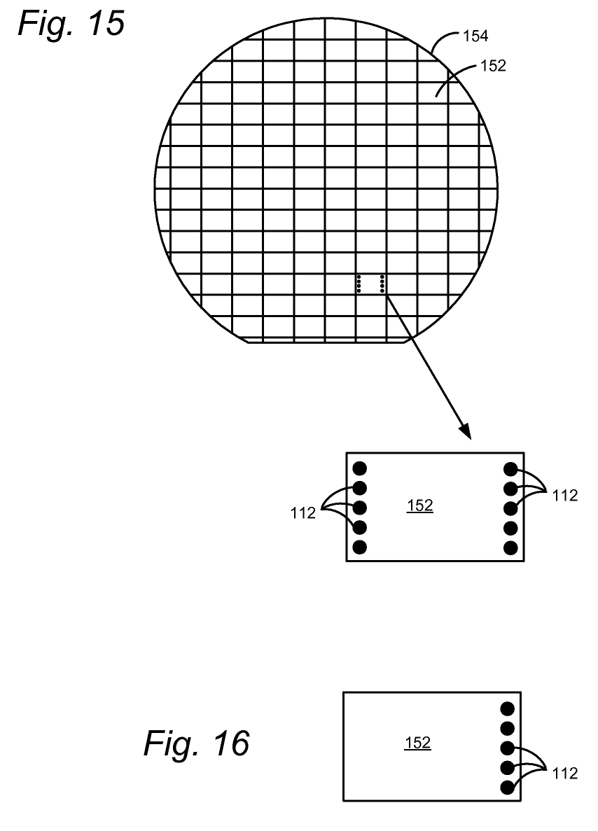

In an embodiment described above, conductive balls 112 are deposited on die bond pads 110 by a wire bonding capillary. However, in a further embodiment of the present invention shown in FIG. 15, conductive balls 112 may be formed at the wafer level on a semiconductor die 152 during fabrication of the semiconductor die itself. Accordingly, as shown in FIGS. 15 and 16, conductive balls 112 are deposited or otherwise formed on a semiconductor wafer 154 in the form of raised surfaces along one or more edges of each semiconductor die 152 on the wafer (while only one semiconductor die is shown with conductive balls 112 in FIG. 15, each of the semiconductor die on the wafer may include the conductive balls). The raised surfaces may be formed along two opposed edges as shown in FIG. 15 or one edge as shown in FIG. 16. It is also contemplated that the raised surfaces be formed along three or four edges of the die 152.

The conductive balls 112 on semiconductor die 152 may be formed by stud bumping, gold bumping, or any known process for forming raised surfaces on a semiconductor die. Such processes are often employed in forming a flip-chip semiconductor die. These processes include but are not limited to plating, evaporation, screen printing, or various deposition processes. As used herein, the raised electrical conductor of a die bond pad may be the layers added to the die bond pad, or it may be the die bond pad plus the layers added to the die bond pad.

Referring again to the embodiments shown in FIGS. 5-10, once the semiconductor die 100 is wire bonded to the substrate 102, the semiconductor die 120 mounted thereon may in turn be wire bonded to substrate 102 in step 206 using additional bond wires in a known wire bond process. Embodiments of the present invention may include only the pair of semiconductor die 100 and 120. However, in further embodiments, more than two semiconductor die may be stacked atop each other. In such embodiments, as indicated by the dashed arrow in FIG. 4, step 202 of applying conductive balls to the die bond pads of the upper die, the step 204 of attaching an additional die and the step 206 of wire bonding the additional die may be repeated for each additional semiconductor die stacked on top of die 120.

Once all semiconductor die are affixed and wire bonded to substrate 102, the semiconductor die may be cured in a reflow process of step 210 to harden any adhesive layers. Curing may be accomplished by a variety of known methods, depending on the adhesive material used, including for example by heating and/or by ultraviolet radiation.

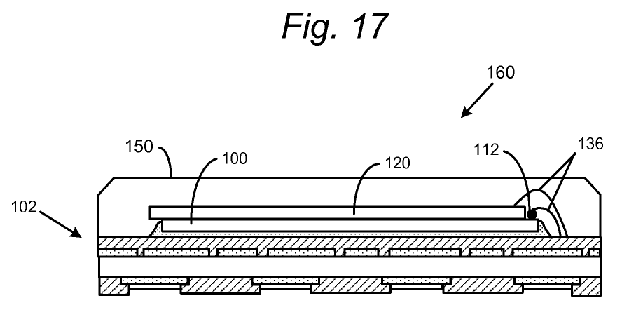

As shown in FIG. 17, after forming the stacked die configuration according to any of the above-described embodiments, the configuration may be encased within the molding compound 150 in step 212, and singulated in step 214, to form a finished semiconductor die package 160. Molding compound 150 may be a known epoxy such as for example available from Sumitomo Corp. and Nitto Denko Corp., both having headquarters in Japan. Thereafter, the finished package 160 may optionally be enclosed within a lid in step 216.

In embodiments, the semiconductor die described above may include one or more flash memory chips, and possibly a controller such as an ASIC, so that the package 160 may be used as a flash memory device. It is understood that the package 160 may include semiconductor die configured to perform other functions in further embodiments of the present invention.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. In a semiconductor package fabrication including first and second semiconductor die, and a wire bonding device for wire bonding electrical leads onto the first and second semiconductor die, the second semiconductor die having a thickness and being stagger stacked near a bond pad on the first semiconductor die such that the wire bonding device is not able to deposit a wire bond on the bond pad of the first semiconductor die without the wire bonding device contacting the second semiconductor die, a method of fabricating a semiconductor package, comprising the steps of:
(a) building up an electrical conductor on the bond pad to a height where the wire bonding device is capable of depositing a wire bond on the electrical conductor without the wire bonding device contacting the second semiconductor die; and
(b) depositing a wire bond on the electrical conductor using the wire bonding device.

2. A method as recited in claim 1, wherein the second semiconductor die is stagger stacked on the first semiconductor die after said step (a) of building up an electrical conductor on the bond pad.

3. A method as recited in claim 1, said step (a) of building up an electrical conductor on the bond pad comprising the step of depositing one or more bond wire balls on the surface of the bond pad using a wire bonding device.

4. A method as recited in claim 3, wherein the wire bonding device deposing one or more bond wire balls in said step (a) is the same wire bonding device depositing a wire bond on the electrical conductor in said step (b).

5. A method as recited in claim 1, said step (a) of building up an electrical conductor on the bond pad comprising the step of using a bumping technique during fabrication of the first semiconductor die.

6. A method as recited in claim 1, said step (a) of building up an electrical conductor on top of the bond pad comprising the step of building up the electrical conductor by one of plating, evaporation and screen printing.

7. A method as recited in claim 1, said step (a) of building up an electrical conductor on top of the bond pad comprising the step of building up the electrical conductor by depositing a discrete amount of conductive material onto the bond pad after formation of the bond pad.

8. A method as recited in claim 7, wherein said step of depositing a discrete amount of conductive material onto the bond pad after formation of the bond pad is performed by a wire bond capillary.

9. A method of fabricating a semiconductor package including first and second stacked semiconductor die, comprising the steps of:
(a) depositing one or more layers of a conductor extending above a surface of the first semiconductor die;
(b) bonding the second semiconductor die on the first semiconductor die adjacent the one or more conductor layers deposited on the first semiconductor die after said step (a); and
(c) wire bonding a wire to the conductor layers deposited in said step (a).

10. A method as recited in claim 9, said step (a) of depositing one or more layers of a conductor extending above a surface of the first semiconductor die comprising the step of depositing one or more bond wire balls on the surface of the first semiconductor die using a wire bonding device.

11. A method as recited in claim 9, said step (a) of depositing one or more layers of a conductor extending above a surface of the first semiconductor die comprising the step of depositing two or more bond wire balls on the surface of the first semiconductor die using a wire bonding device.

12. A method as recited in claim 9, said step (a) of depositing one or more layers of a conductor extending above a surface of the first semiconductor die comprising the step of depositing the conductor layers by one of plating, evaporation and screen printing.

13. A method as recited in claim 9, further comprising the steps of:
(d) depositing one or more layers of a conductor extending above a surface of the second semiconductor die;
(e) bonding a third semiconductor die on the second semiconductor die adjacent the one or more conductor layers deposited on the second semiconductor die after said step (d); and
(f) wire bonding a wire to the conductor layers deposited in said step (d).

14. A method as recited in claim 13, wherein said steps (a), (b), (d) and (e) are performed prior to said steps (c) and (f).

15. A method as recited in claim 9, said step (c) of wire bonding a wire to the conductor layers comprising the step of forming a bond loop with a wire bonding device.

16. A method as recited in claim 9, said step (c) of wire bonding a wire to the conductor layers comprising the step of forming a bond loop by reverse wire bonding.

17. A method of fabricating a semiconductor package including first and second stacked semiconductor die, comprising the steps of:
(a) forming one or more layers of a conductor extending above a surface of a semiconductor die of a semiconductor wafer during fabrication of the wafer;
(b) singulating the semiconductor die from the semiconductor wafer;
(c) bonding the second semiconductor die onto the first semiconductor die adjacent the one or more layers deposited on the first semiconductor die after said step (a); and
(d) wire bonding a wire to the conductor deposited in said step (a).

18. A method as recited in claim 17, said step (a) of forming one or more layers of a conductor extending above a surface of a semiconductor die of a semiconductor wafer comprising the step of using a bumping technique to apply the one or more layers of a conductor onto a surface of a semiconductor die of a semiconductor wafer.

19. A method as recited in claim 17, said step (a) of forming one or more layers of a conductor extending above a surface of a semiconductor die of a semiconductor wafer comprising the step of applying the one or more layers by one of plating, evaporation and screen printing.

20. A method as recited in claim 17, said step (d) of wire bonding a wire to the conductor layers comprising the step of forming a bond loop by reverse wire bonding.
